(19) United States
(12) Patent Application Publication
(10) Pub. No.: US 2023/0090605 A1
(43) Pub. Date: Mar. 23, 2023

(54) METHOD FOR PRODUCING LIGHT-EMITTING DEVICE, AND LIGHT-EMITTING DEVICE

(71) Applicant: SHARP KABUSHIKI KAISHA, Sakai City, Osaka (JP)

(72) Inventor: Masumi KUBO, Sakai City, Osaka (JP)

(21) Appl. No.: 17/795,086

(22) PCT Filed: Feb. 6, 2020
(86) PCT No.: PCT/JP2020/004600

§ 371 Date: Jul. 25, 2022

(51) Int. Cl. H01L 33/04

(52) U.S. Cl. CPC H01L 33/04

(57) ABSTRACT

A method for manufacturing a light-emitting device includes performing application, performing temperature raising, and performing first light irradiation. In the performing application, a solution including quantum dots, a ligand, an inorganic precursor, and a solvent is applied on a position overlapping with the substrate. The quantum dots each includes a core and a first shell coating the core. In the performing temperature raising, a temperature is raised until the ligand melts and the solvent vaporizes after the performing application. In the performing first light irradiation, light irradiation is performed after the performing temperature raising. In the performing first light irradiation, the inorganic precursor is epitaxially grown around the first shell to form a second shell coating the first shell, and an inorganic film in which the inorganic precursor is epitaxially grown at an interface between the quantum dot layer and the first charge transport layer is formed.

### TECHNICAL FIELD

The present invention relates to a method for manufacturing a light-emitting device provided with a light-emitting element including quantum dots, and the light-emitting device.

### BACKGROUND ART

PTL 1 discloses a semiconductor nanoparticle (quantum dot) having a core/shell structure and a ligand that coordinates with the semiconductor nanoparticle.

### CITATION LIST

### Patent Literature

PTL 1: JP 2017-025220 A

### Non Patent Literature

NPL 1: Tanemura Masami, “Random Packing (Physics on Form, Workshop Report)”, Bussei Kenkyu (1984), 42 (1), 76-77

### SUMMARY OF INVENTION

### Technical Problem

An improvement in luminous efficiency is desired in a light-emitting device including a quantum dot layer.

### Solution to Problem

A method for manufacturing a light-emitting device according to an aspect of the present invention is a method for manufacturing a light-emitting device including, on a substrate, a light-emitting element including a first electrode, a second electrode, a quantum dot layer between the first electrode and the second electrode, and a first charge transport layer between the first electrode and the quantum dot layer. The method for manufacturing a light-emitting device includes performing electrode formation and forming the quantum dot layer. In the performing electrode formation, the first electrode including an oxide semiconductor film on a surface is formed on the substrate. In the forming the quantum dot layer, the quantum dot layer is formed subsequent to the performing electrode formation. The forming the quantum dot layer includes performing application, performing temperature raising, and performing first light irradiation. In the performing application, a solution including a plurality of quantum dots, a ligand, an inorganic precursor, and a solvent is applied on a position overlapping with the substrate, the plurality of quantum dots each including a core and a first shell coating the core, the ligand coordinating with each of the plurality of quantum dots. In the performing temperature raising, a temperature is raised until the ligand melts and the solvent vaporizes after the performing application. In the performing first light irradiation, light irradiation is performed after the performing temperature raising. In the performing first light irradiation, the inorganic precursor is epitaxially grown around the first shell to form a second shell coating the first shell, and an inorganic film in which the inorganic precursor is epitaxially grown at an interface between the quantum dot layer and the first charge transport layer is formed.

A light-emitting device according to an aspect of the present invention is a light-emitting device including, on a substrate, a light-emitting element including a first electrode, a second electrode, a quantum dot layer between the first electrode and the second electrode, and a first charge transport layer between the first electrode and the quantum dot layer. The light-emitting device includes a plurality of quantum dots and an inorganic film. The plurality of quantum dots each includes a core, a first shell coating the core, and a second shell coating the first shell. The inorganic film is formed at an interface between the quantum dot layer and the first charge transport layer.

### Advantageous Effects of Invention

According to the configurations described above, luminous efficiency may be further improved in a light-emitting device provided with quantum dots.

### BRIEF DESCRIPTION OF DRAWINGS

FIG. 1A is a schematic top view of a light-emitting device according to a first embodiment. FIG. 1B is a schematic cross-sectional view of the light-emitting device according to the first embodiment. FIG. 1C is a schematic enlarged view of a periphery of a light-emitting layer of the light-emitting device according to the first embodiment.

FIG. 2 is a flowchart for describing a method for manufacturing the light-emitting device according to the first embodiment.

FIG. 3 is a flowchart for describing a method for forming the light-emitting layer according to the first embodiment.

FIGS. 4A and 4B are forming-step cross-sectional views for describing a step of forming the light-emitting layer according to the first embodiment.

FIGS. 5A and 5B are another forming-step cross-sectional views for describing the step of forming the light-emitting layer according to the first embodiment.

FIGS. 6A to 6C are forming-step cross-sectional views for describing light irradiation using a photomask in the step of forming the light-emitting layer according to the first embodiment.

FIGS. 7A to 7C are another forming-step cross-sectional views for describing light irradiation using a photomask in the step of forming the light-emitting layer according to the first embodiment.

FIG. 8A is a schematic top view of a light-emitting device according to a second embodiment. FIG. 8B is a schematic cross-sectional view of the light-emitting device according to the second embodiment. FIG. 8C is a schematic enlarged view of a periphery of a light-emitting layer of the light-emitting device according to the second embodiment.

FIG. 9A is a schematic top view of a light-emitting device according to a third embodiment. FIG. 9B is a schematic cross-sectional view of the light-emitting device according to the third embodiment. FIG. 9C is a schematic enlarged view of a periphery of a light-emitting layer of the light-emitting device according to the first embodiment.

FIG. 10 is a flowchart for describing a method for forming the light-emitting layer according to the third embodiment.

FIGS. 11A and 11B are forming-step cross-sectional views for describing a step of forming the light-emitting layer according to the third embodiment.

FIG. 12A is a schematic top view of a light-emitting device according to a fourth embodiment. FIG. 12B is a schematic cross-sectional view of the light-emitting device according to the fourth embodiment. FIG. 12C is a schematic enlarged view of a periphery of a light-emitting layer of the light-emitting device according to the fourth embodiment.

FIGS. 13A to 13C are forming-step cross-sectional views for describing a step of forming the light-emitting layer and a step of forming a second electron transport layer according to the fourth embodiment.

FIGS. 14A to 14D are another forming-step cross-sectional views for describing the step of forming the light-emitting layer and the step of forming the second electron transport layer according to the fourth embodiment.

### DESCRIPTION OF EMBODIMENTS

### First Embodiment

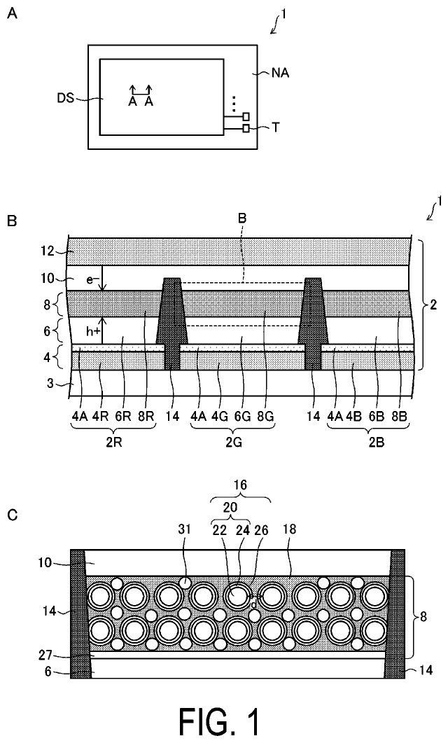

FIG. 1A is a schematic top view of a light-emitting device 1 according to the present embodiment. FIG. 1B is a cross-sectional view taken along a line A-A in FIG. 1A. FIG. 1C is an enlarged cross-sectional view of a region B in FIG. 1B, that is, an enlarged cross-sectional view of a perimeter of a second light-emitting layer 8G to be described later.

As illustrated in FIG. 1A, the light-emitting device 1 according to the present embodiment includes a light-emitting face DS from which light emission is extracted and a frame region NA surrounding a periphery of the light-emitting face DS. In the frame region NA, a terminal T may be formed into which a signal for driving a light-emitting element of the light-emitting device 1 described in detail later is input.

At a position overlapping with the light-emitting face DS in plan view, as illustrated in FIG. 1B, the light-emitting device 1 according to the present embodiment includes a light-emitting element layer 2 and an array substrate 3. The light-emitting device 1 has a structure in which respective layers of the light-emitting element layer 2 are layered on the array substrate 3, in which a thin film transistor (TFT; not illustrated) is formed. In the present specification, a direction from the light-emitting element layer 2 to the array substrate 3 of the light-emitting device 1 is referred to as “downward direction”, and a direction from the light-emitting element layer 2 to the light-emitting face DS of the light-emitting device 1 is referred to as “upward direction”.

The light-emitting element layer 2 includes, on a first electrode 4, a first charge transport layer 6, a light-emitting layer 8 as a quantum dot layer, a second charge transport layer 10, and a second electrode 12, which are sequentially layered from the lower layer. The first electrode 4 of the light-emitting element layer 2 formed in the upper layer of the array substrate 3 is electrically connected to the TFT of the array substrate 3. In the present embodiment, the first electrode 4 is an anode electrode and the second electrode 12 is a cathode electrode, for example.

In the present embodiment, the light-emitting element layer 2 includes a first light-emitting element 2R, a second light-emitting element 2G, and a third light-emitting element 2B. The first light-emitting element 2R, the second light-emitting element 2G, and the third light-emitting element 2B are quantum-dot light emitting diode (QLED) elements in which the light-emitting layer 8 includes a semiconductor nanoparticle material, that is, a quantum dot material, and the quantum dot material is caused to emit light in the light-emitting layer 8.

Each of the first electrode 4, the first charge transport layer 6, and the light-emitting layer 8 is separated by edge covers 14. In particular, in the present embodiment, the first electrode 4 is, by the edge covers 14, separated into a first electrode 4R for the first light-emitting element 2R, a first electrode 4G for the second light-emitting element 2G, and a first electrode 4B for the third light-emitting element 2B. The first charge transport layer 6 is, by the edge covers 14, separated into a first charge transport layer 6R for the first light-emitting element 2R, a first charge transport layer 6G for the second light-emitting element 2G, and a first charge transport layer 6B for the third light-emitting element 2B. Further, the light-emitting layer 8 is, by the edge covers 14, separated into a first light-emitting layer 8R, the second light-emitting layer 8G, and a third light-emitting layer 8B.

The second charge transport layer 10 and the second electrode 12 are not separated by the edge covers 14, and are each formed in a shared manner. As illustrated in FIG. 1B, the edge covers 14 may be formed at the positions to cover side surfaces of the first electrode 4 and the vicinity of peripheral end portions of an upper face thereof.

In the present embodiment, the first light-emitting element 2R includes the first electrode 4R, the first charge transport layer 6R, the first light-emitting layer 8R, the second charge transport layer 10, and the second electrode 12. The second light-emitting element 2G includes the first electrode 4G, the first charge transport layer 6G, the second light-emitting layer 8G, the second charge transport layer 10, and the second electrode 12. Furthermore, the third light-emitting element 2B includes the first electrode 4B, the first charge transport layer 6B, the third light-emitting layer 8B, the second charge transport layer 10, and the second electrode 12.

In the present embodiment, the first light-emitting layer 8R, the second light-emitting layer 8G, and the third light-emitting layer 8B emit red light that is light of a first color, green light that is light of a second color, and blue light that is light of a third color, respectively. In other words, the first light-emitting element 2R, the second light-emitting element 2G, and the third light-emitting element 2B are light-emitting elements that emit the red light, the green light, and the blue light, respectively, which are different colors from each other.

Here, the blue light refers to, for example, light having a light emission central wavelength in a wavelength band of equal to or greater than 400 nm and equal to or less than 500 nm. The green light refers to, for example, light having a light emission central wavelength in a wavelength band of greater than 500 nm and equal to or less than 600 nm. The red light refers to, for example, light having a light emission central wavelength in a wavelength band of greater than 600 nm and equal to or less than 780 nm.

The first electrode 4 and the second electrode 12 include conductive materials and are electrically connected to the first charge transport layer 6 and the second charge transport layer 10, respectively. Of the first electrode 4 and the second electrode 12, the electrode closer to the light-emitting face DS is a transparent electrode.

In particular, in the present embodiment, the array substrate 3 is a transparent substrate, and the first electrode 4 is a transparent electrode. The second electrode 12 may be a reflective electrode. Therefore, light from the light-emitting layer 8 passes through the first charge transport layer 6, the first electrode 4, and the array substrate 3, and is emitted from the light-emitting face DS to the outside of the light-emitting device 1. Due to this, the light-emitting device 1 is configured as a bottom-emitting type light-emitting device. Since both the light emitted in the upward direction from the light-emitting layer 8 and the light emitted in the downward direction from the light-emitting layer 8 are available as light emission from the light-emitting device 1, the light-emitting device 1 can improve the usage efficiency of the light emitted from the light-emitting layer 8.

In the present embodiment, each first electrodes 4 includes an oxide semiconductor film 4A on a surface. The oxide semiconductor film 4A may include a transparent oxide semiconductor such as ITO, for example. In the present embodiment, the oxide semiconductor film 4A has a function of absorbing light and generating heat. In particular, it is preferable that the oxide semiconductor film 4A generates heat by irradiating the oxide semiconductor film 4A with ultraviolet light, for example.

Note that the present embodiment illustrates a case where the first electrode 4 includes a thin film of the oxide semiconductor film 4A on the surface, which is not limited thereto. For example, the entire first electrode 4 may be formed of the same material as the oxide semiconductor film 4A.

Note that the configuration of the first electrode 4 and the second electrode 12 described above is an example, and may be configured with other materials.

The first charge transport layer 6 is a layer that transports charges from the first electrode 4 to the light-emitting layer 8. The first charge transport layer 6 may have a function of inhibiting the transport of charges from the second electrode 12. In the present embodiment, the first charge transport layer 6 may be a hole transport layer that transports positive holes from the first electrode 4, which is an anode electrode, to the light-emitting layer 8.

The second charge transport layer 10 is a layer that transports the charge from the second electrode 12 to the light-emitting layer 8. The second charge transport layer 10 may have a function of inhibiting the transport of the charges from the first electrode 4. In the present embodiment, the second charge transport layer 10 may be an electron transport layer that transports electrons from the second electrode 12, which is a cathode electrode, to the light-emitting layer 8.

Next, the configuration of the light-emitting layer 8 will be described in detail with reference to FIG. 1C. Note that, FIG. 1C is a schematic cross-sectional view of the region B in FIG. 1B, that is, a schematic cross-sectional view of the periphery of the second light-emitting layer 8G of the second light-emitting element 2G. However, in the present embodiment, unless otherwise indicated, members illustrated in FIG. 1C are considered to have configurations common to each of the light-emitting elements. Accordingly, in the present embodiment, unless otherwise indicated, the members illustrated in FIG. 1C may have the same configurations as those in each of the light-emitting elements.

In the present embodiment, the light-emitting layer 8 includes a quantum dot structure 16 and a ligand 18. The quantum dot structure 16 includes each of a plurality of (first) quantum dots 20. The quantum dot 20 has a core/shell structure including a core 22 and a first shell 24, with which the periphery of the core 22 is coated. The quantum dot structure 16 includes a second shell 26 and an inorganic film 27. The second shell 26 coats a periphery of the first shell 24 being an outer shell of each of the quantum dots 20. The inorganic film 27 is formed at an interface between the light-emitting layer 8 and the first charge transport layer 6.

The quantum dot 20 may have a multi-shell structure in which a plurality of shells are provided around the core 22. In this case, the first shell 24 refers to a shell corresponding to the outermost layer among the plurality of shells.

The ligand 18 may coordinate with the quantum dot structure 16 on an outer surface of the second shell 26 to fill a void in the quantum dot structure 16. The ligand 18 may be, for example, trioctylphosphine oxide (TOPO).

The first shell 24 and the second shell 26 have a crystal structure, and in particular, in the present embodiment, the second shell 26 has a crystal structure formed by epitaxial growth on the first shell 24. The first shell 24 and the second shell 26 may be polycrystalline. In the present embodiment, the quantum dot 20 is separated from the other quantum dot 20. Specifically, the ligand 18 is interposed between the plurality of quantum dots 20. Note that, among the plurality of quantum dots 20, at least one set of quantum dots 20 adjacent to each other may be connected to each other via the second shell 26.

The core 22 and first shell 24 of the quantum dot 20 may include an inorganic material used for the quantum dots of a known core/shell structure. In other words, the first light-emitting layer 8R, the second light-emitting layer 8G, and the third light-emitting layer 8B may include known quantum dot materials used for light-emitting layers of red, green, and blue QLED elements, respectively.

In addition, similar to the first shell 24, the second shell 26 may include an inorganic shell material used for the quantum dots of a known core/shell structure. The first shell 24 and the second shell 26 may be made of the same material. Note that a specific resistance of the second shell 26 is preferably equal to or greater than a specific resistance of the first shell 24. Further, the size of a band gap of the second shell 26 is preferably greater than the size of a band gap of the first shell 24. With this configuration, the efficiency of charge injection from the second shell 26 to the first shell 24 is improved.

The inorganic film 27 has a crystal structure. In particular, in the present embodiment, the inorganic film 27 has a crystal structure formed by epitaxial growth on the first charge transport layer 6. The inorganic film 27 is formed of the same material as the second shell 26. The inorganic film 27 and the second shell 26 are separated from each other. Specifically, the ligand 18 is interposed between the inorganic film 27 and the second shell 26.

Examples of specific materials for the core 22 include group II-VI semiconductors such as CdSe (band gap 1.73 eV), CdTe (band gap 1.44 eV), ZnTe (band gap 2.25 eV), and CdS (band gap 2.42 eV). Examples of other specific materials for the core 22 include the group III-V such as InP (band gap 1.35 eV) and InGaP (band gap 1.88 eV).

In general, the wavelength emitted by the quantum dot is determined by the particle diameter of the core. Therefore, it is preferable to employ a semiconductor material having an appropriate band gap as a material of the core 22 in order to control the light emitted from the core 22 to be any of red, green, and blue colors, by controlling the particle diameter of the core 22.

The band gap of the material of the core 22 included in the first light-emitting layer 8R is preferably equal to or lower than 1.97 eV in order for the first light-emitting layer 8R serving as a red light-emitting layer to emit red light having a wavelength of 630 nm. In order for the second light-emitting layer 8G serving as a green light-emitting layer to emit green light having a wavelength of 532 nm, the band gap of the material of the core 22 included in the second light-emitting layer 8G is preferably equal to or lower than 2.33 eV. Furthermore, in order for the third light-emitting layer 8B serving as a blue light-emitting layer to emit blue light having a wavelength of 630 nm, the band gap of the material of the core 22 included in the third light-emitting layer 8B is preferably equal to or lower than 2.66 eV. The light-emitting device 1 provided with the first light-emitting layer 8R, the second light-emitting layer 8G, and the third light-emitting layer 8B is preferable from the perspective of satisfying the color space criteria in the International Standard BT 2020 of UHDTV.

Examples of specific materials for the first shell 24, the second shell 26, and the inorganic film 27 include the group II-VI such as ZnSe (band gap 2.7 eV) and ZnS (band gap 3.6 eV), and the group III-V such as GaP (band gap 2.26 eV).

The material of the core 22 preferably has low specific resistance and a less band gap compared to the material of the first shell 24, the second shell 26, and the inorganic film 27. With this configuration, the efficiency of charge injection from the first shell 24, the second shell 26, and the inorganic film 27 to the core 22 is improved.

Note that, in the present embodiment, an average film thickness of the first shell 24 from the outer surface of the core 22 is less than a minimum film thickness of the second shell 26. Here, the minimum film thickness of the second shell 26 refers to the least film thickness of a film thickness from the first shell 24 to the outer surface of the second shell 26.

As illustrated in FIG. 1C, the shortest distance from the core 22 of one quantum dot 20 to the core 22 of another quantum dot 20 adjacent thereto is defined as d. For example, when the core 22 is made of InP, and the first shell 24 and second shell 26 are made of ZnS, an average value of the distance d is preferably equal to or greater than 3 nm. For example, when the core 22 is made of CdSe, and the first shell 24 and second shell 26 are made of ZnS, an average value of the distance d is preferably equal to or greater than 1 nm. With this configuration, the electron exudation from the core 22, derived from the electron wave function, may be efficiently reduced by the first shell 24 and the second shell 26.

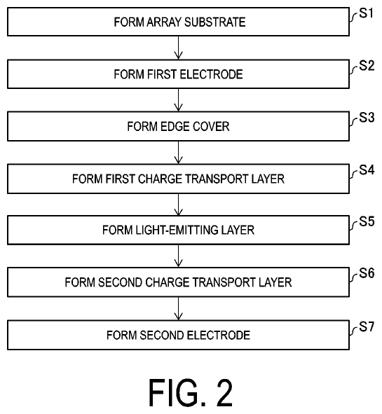

Next, a method for manufacturing the light-emitting device 1 according to the present embodiment will be described with reference to FIG. 2. FIG. 2 is a flowchart for describing the method for manufacturing the light-emitting device 1 according to the present embodiment.

First, an array substrate is formed (step S1). Formation of the array substrate may be performed by forming a plurality of TFTs on the substrate to match positions of the subpixels.

Next, as a step of forming an electrode, the first electrode 4 is formed (step S2). In step S2, for example, after a transparent electrode material having electrical conductivity, such as ITO, is film-formed by sputtering, the first electrode 4 may be formed for each subpixel by patterning while matching a shape of the subpixel. Alternatively, the first electrode may be formed for each subpixel by vapor-depositing a transparent electrode material by using a vapor deposition mask.

Next, the edge covers 14 are formed (step S3). The edge covers 14, after being applied on the array substrate 3 and the first electrode 4, may be obtained by patterning while leaving the positions covering the side surfaces and peripheral end portions of the first electrodes 4 between the adjacent first electrodes 4. The patterning of the edge covers 14 may be performed by photolithography.

Next, the first charge transport layer 6 is formed (step S4). The first charge transport layer 6 may be formed for each subpixel by separately patterning with an ink-jet method, vapor deposition using a mask, or patterning using photolithography.

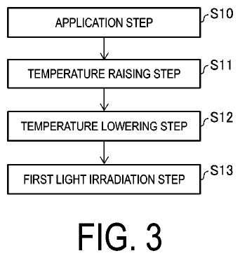

Next, the light-emitting layer 8 is formed (step S5). The step of forming the light-emitting layer 8 will be described in more detail with reference to FIGS. 3 to 5B.

FIG. 3 is a flowchart for describing the step of forming the light-emitting layer corresponding to a step of forming a quantum dot layer in the present embodiment.

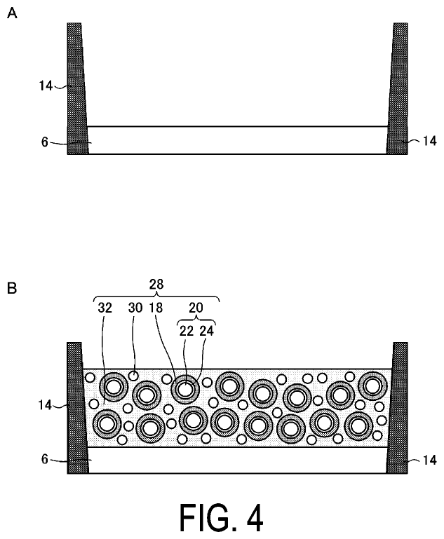

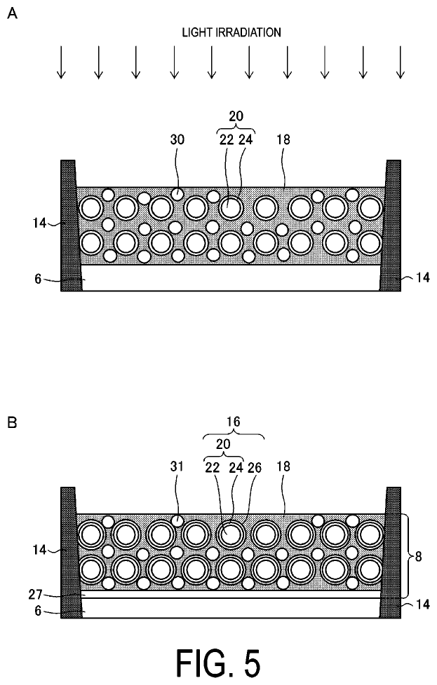

FIGS. 4A to 5B are forming-step cross-sectional views for describing the step of forming the light-emitting layer. Hereinafter, each of the forming-step cross-sectional views including FIGS. 4A to 5B of the present specification illustrates the forming-step cross-sectional view of the region B in FIG. 1B, that is, the forming-step cross-sectional view at the position corresponding to the periphery of the second light-emitting layer 8G of the second light-emitting element 2G, unless otherwise specified. However, the techniques described with reference to the forming-step cross-sectional views in the present specification may be applied to the method for forming the light-emitting layer 8 of the other light-emitting elements, unless otherwise specified.

As illustrated in FIG. 4A, the formation up to the first charge transport layer 6 has been performed on the array substrate 3 until the step of forming the light-emitting layer. In the step of forming the light-emitting layer, first, a step of application is performed in which a solution 28 illustrated in FIG. 4B is applied on a position overlapping with the array substrate 3 (step S10).

The solution 28 is a solution in which the plurality of quantum dots 20 with the ligand 18 being coordinated and an inorganic precursor 30 are dispersed in a solvent 32, as illustrated in FIG. 4B. The solvent 32 may be, for example, hexane. The inorganic precursor 30 contains the same material as the second shell 26 and the inorganic film 27 described above. The inorganic precursor 30 may contain, for example, zinc chloride and 1-Dodecanethiol.

The step of the application is performed at an atmospheric temperature of a temperature T0. Since the application of the solution 28 is performed at the atmospheric temperature of the temperature T0, the temperature of the quantum dots 20 in the solution 28 to be applied and an ambient temperature of the quantum dots 20 also take the temperature T0. The temperature T0 may be, for example, an ordinary temperature.

Subsequently, a step of temperature raising is performed in which the solution 28 on the array substrate 3 is heated (step S11). In the step of the temperature raising, for example, the temperature of the solution 28 is raised by baking treatment (heat treatment) of the array substrate 3. In the step of the temperature raising, the solution 28 is heated until the temperature of the solution 28 is equal to or higher than the first temperature T1.

The first temperature T1 is a temperature equal to or higher than both of a melting point T2 of the ligand 18 and a melting point of the solvent 32. The first temperature T1 is higher than the temperature T0. Therefore, in the step of the temperature raising, the ligand 18 melts and the solvent 32 vaporizes.

The melting point of TOPO is in a range from 50 degrees Celsius to 54 degrees Celsius, and the boiling point of hexane is in a range from 68.5 degrees Celsius to 69.1 degrees Celsius. Accordingly, in a case where the ligand 18 is TOPO and the solvent is hexane, the first temperature T1 is the boiling point of the hexane. That is, the boiling point T1 of the solvent 32 is equal to or higher than the melting point T2 of the ligand 18. Therefore, in the step of the temperature raising, the solvent 32 vaporizes after the ligand 18 has melted.

Note that, in the step of the temperature raising, light irradiation in which light such as ultraviolet rays is emitted may be performed on the solution 28 on the array substrate 3 instead of the baking treatment. By the light irradiation, the oxide semiconductor film 4A and the quantum dot 20 absorb light (ultraviolet rays) and generate heat, and thus the temperature of the solution 28 rises.

After the completion of the step of the temperature raising, as illustrated in FIG. 5A, the solvent 32 has vaporized from above the array substrate 3, and the quantum dots 20 and the inorganic precursor 30 are dispersed in the melted ligand 18.

Next, a step of temperature lowering is performed in which the temperature of the ligand 18 on the array substrate 3 is reduced (step S12). In the step of the temperature lowering, the temperature of the ligand 18 is reduced by natural heat dissipation, for example. In the step of the temperature lowering, the temperature is reduced until the temperature of the ligand 18 becomes equal to or lower than the melting point T2 of the ligand 18. In the step of the temperature lowering, the temperature of the ligand 18 falls below the melting point T2, thereby solidifying the melted ligand 18. That is, the ligand 18 solidifies while the quantum dots 20 and the inorganic precursor 30 are dispersed.

Subsequently, a step of first light irradiation is performed in which first light irradiation is performed on the position where the solution 28 has been applied on the array substrate 3 (step S13). In the step of the first light irradiation, the position where the solution 28 has been applied on the array substrate 3 is irradiated with light such as ultraviolet rays. That is, in the step of the first light irradiation, the solidified ligand 18 is irradiated with ultraviolet rays while the quantum dots 20 and the inorganic precursor 30 are dispersed. In the step of the first light irradiation, the oxide semiconductor film 4A and the core 22 of the quantum dot 20 absorb light to generate heat. The heat generated from the oxide semiconductor film 4A is transmitted to the ligand 18 via the first charge transport layer 6.

Therefore, in the step of the first light irradiation, the temperature near the first charge transport layer 6 and around the quantum dot 20 in the ligand 18 locally rises due to the heat generation of the oxide semiconductor film 4A and the core 22. In this way, the temperature near the first charge transport layer 6 and around the quantum dot 20 in the ligand 18 exceeds the melting point T2 of the ligand 18, and the ligand 18 partially melts again.

Then, when the temperature near the first charge transport layer 6 and around the quantum dot 20 in the ligand 18 exceeds a reaction temperature T3 of the inorganic precursor 30, the inorganic precursor 30 epitaxially grows by thermochemical reaction. The reaction temperature T3 is a temperature higher than the melting point T2 of the ligand 18, and when the inorganic precursor 30 contains zinc chloride and 1-Dodecanethiol, the reaction temperature T3 is approximately 200 degrees Celsius.

The inorganic precursor 30 contained in the melted ligand 18 epitaxially grows near the first charge transport layer 6 in the ligand 18. In this way, as illustrated in FIG. 5B, the film-shaped inorganic film 27 formed by epitaxially growing the inorganic precursor 30 is formed at the interface between the light-emitting layer 8 and the first charge transport layer 6. In other words, the inorganic film 27 is formed on the surface of the first charge transport layer 6 on the light-emitting layer 8 side. The inorganic film 27 is formed such that the film thickness gradually increases from the surface of the first charge transport layer 6. Therefore, the adhesion of the inorganic film 27 to the first charge transport layer 6 is improved, and the film thickness of the inorganic film 27 can be made uniform. In this way, the carrier injection to the core 22 can be made uniform, and the luminous efficiency can be improved.

Further, the inorganic precursor 30 contained in the melted ligand 18 epitaxially grows around the quantum dot 20 in the ligand 18. In this way, as illustrated in FIG. 5B, the second shell 26 formed by epitaxially growing the inorganic precursor 30 is formed so as to cover the periphery of the first shell 24. The second shell 26 is formed around the quantum dot 20 such that the film thickness gradually increases from the outer surface of the first shell 24.

In the present embodiment, the first light irradiation is stopped while the inorganic film 27 and the second shell 26 are separated from each other. In other words, the step of the first light irradiation is completed before the inorganic film 27 and the second shell 26 are connected to each other. The inorganic film 27 and the second shell 26 are separated from each other, and thus each second shell 26 is surrounded by the ligand 18. In this way, the carrier injection to the core 22 can be made uniform, and light emission unevenness can be suppressed.

In the present embodiment, while the ligand 18 locally melts only near the first charge transport layer 6 and around the quantum dot 20 and the other solidifies, the inorganic precursor 30 epitaxially grows. Therefore, contamination of impurities and the like into the ligand 18 can be suppressed.

Then, when the first light irradiation is stopped, the temperature of the ligand 18 is reduced, and when the temperature of the ligand 18 falls below the melting point T2, the ligand 18 entirely solidifies. In this way, the light-emitting layer 8 that includes the quantum dot structure 16 including the quantum dot 20 and the second shell 26, and the inorganic film 7 is formed.

Further, second quantum dots 31 generated from the inorganic precursor 30, which is not used for generating the second shell 26 or the inorganic film 27, are present in a dispersed manner in the solidified ligand 18. In this way, the light emission amount of the quantum dots 20 increases by the light emission of the second quantum dots 31, and thus the luminous efficiency can be improved.

Note that in the present embodiment, the step of forming the light-emitting layer 8 is described with reference to the enlarged cross-sectional view of the periphery of the second light-emitting layer 8G. However, a difference in the forming method of each of the first light-emitting layer 8R, second light-emitting layer 8G, and third light-emitting layer 8B is only a difference in the materials contained in the solution 28. That is, regardless of luminescent colors of the light-emitting layer 8 to be formed, the steps of the application, the temperature raising, the temperature lowering, and the first light irradiation may be implemented by the same method.

In the step of the application, the material contained in the solution 28 may be changed for each luminescent color of the corresponding light-emitting element, and the solution 28 may be subjected to separately patterning by an ink-jet method. Specifically, the solution 28 may be separately applied by an ink-jet method on a position overlapping with each of the first electrodes 4 formed for each light-emitting element. Then, the steps of the temperature raising, the temperature lowering, and the first light irradiation described above may be performed. As a result, the light-emitting elements having mutually different luminescent colors can be formed by continuous single light irradiation.

Note that the concentration of the inorganic precursor 30 in the solution 28 applied in the step of the application may vary depending on a luminescent color of the corresponding light-emitting element. In particular, the concentration of the inorganic precursor 30 in the solution 28 applied on the position corresponding to the second light-emitting element 2G is preferably lower than the concentration of the inorganic precursor 30 in the solution 28 applied on the position corresponding to the first light-emitting element 2R. Furthermore, the concentration of the inorganic precursor 30 in the solution 28 applied on the position corresponding to the second light-emitting element 2G is preferably higher than the concentration of the inorganic precursor 30 in the solution 28 applied on the position corresponding to the third light-emitting element 2B.

In the step of epitaxially growing the second shell 26 around the quantum dot 20, when the amount of light irradiation is the same, the amount of the inorganic precursor 30 needed for forming the second shell 26 having the same film thickness increases as a particle size of the quantum dot 20 increases. In general, as a wavelength of light emitted from the quantum dot 20 increases, a particle size of the core 22, and thus a particle size of the quantum dot 20 increases.

Therefore, as in the configuration described above, with a longer wavelength of light emitted from the corresponding light-emitting element, a formation condition of each light-emitting layer can be brought closer by increasing the concentration of the inorganic precursor 30 in the solution 28. Thus, a variation in film thickness of the second shell 26 can be suppressed between the quantum dots 20 having particle sizes different from each other.

In the step of forming the light-emitting layer, after the solution 28 is applied on a position overlapping with the first electrode 4 in the step of the application, partial exposure by laser irradiation may be performed in the first light irradiation. Thereafter, a step of removal may be performed in which the solution 28 is removed from a position overlapping with a position different from the position where the partial exposure was performed. As a result, the light-emitting layer 8 may be formed only at the position partially exposed by the laser irradiation.

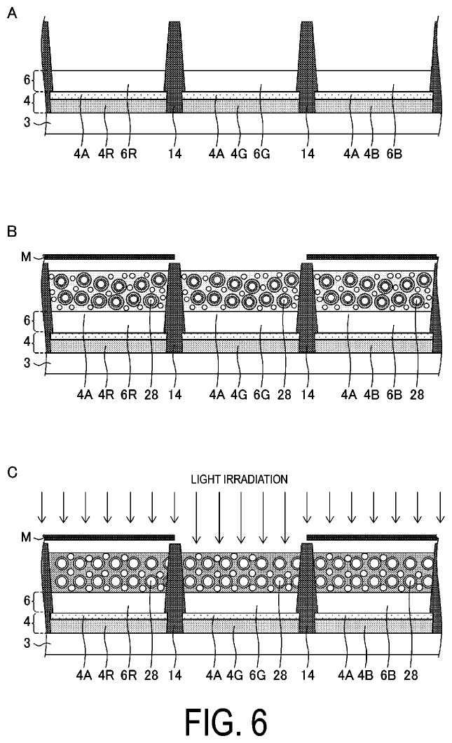

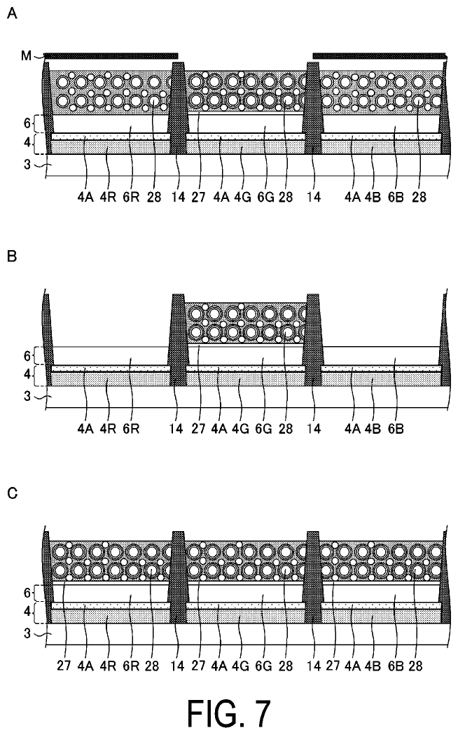

Furthermore, in the step of forming the light-emitting layer, after the solution 28 is applied on a position overlapping with the first electrode 4 in the step of the application, partial exposure using a photomask may be performed in the first light irradiation. A method for forming the light-emitting layer 8 by partial exposure using a photomask will be described in more detail with reference to FIGS. 6A to 7C.

FIGS. 6A to 7C are forming-step cross-sectional views for describing a technique for forming the light-emitting layer 8 by partial exposure using a photomask in the step of forming the light-emitting layer. Note that FIGS. 6A to 7C illustrate not only a position where the second light-emitting layer 8G is formed, but also illustrate a position where the first light-emitting layer 8R and the third light-emitting layer 8B are formed.

As illustrated in FIG. 6A, the first electrode 4 and the first charge transport layer 6 that are partitioned by the edge covers 14 are formed on the array substrate 3 immediately before the step of forming the light-emitting layer is performed. Here, a photomask M illustrated in FIG. 6B is installed between the step of the application and the step of the first light irradiation.

The photomask M has a function of shielding light emitted in the step of the light irradiation. When the photomask M is installed above the array substrate 3, an opening is formed such that the opening is formed only in a position overlapping with the first electrode 4G. That is, as illustrated in FIG. 6B, when the photomask M is installed above the array substrate 3, the top of the solution 28 in a position that does not overlap with the first electrode 4G is shielded by the photomask M. Thereafter, the step of the temperature raising and the step of the temperature lowering are performed. Note that the installation of the photomask M may be performed before or after the step of the temperature raising and the step of the temperature lowering, or may be performed between the step of the temperature raising and the step of the temperature lowering.

By performing the step of the first light irradiation after the photomask M is installed, light irradiation is performed only on the oxide semiconductor film 4A in the position overlapping with the first electrode 4G, as illustrated in FIG. 6C. Thus, in the step of the first light irradiation, the quantum dots 20 and the oxide semiconductor film 4A are heated only in the position overlapping with the first electrode 4G. Therefore, as illustrated in FIG. 7A, the second light-emitting layer 8G including the second shell 26 and the inorganic film 27 is formed only in the position overlapping with the first electrode 4G.

Next, after the photomask M is removed from above the array substrate 3, as illustrated in FIG. 7B, the step of the removal is performed in which the solution 28 is removed from a position overlapping with a position different from the position where the light irradiation is performed. In this way, the step of forming the second light-emitting layer 8G is completed.

Note that, in the step of forming the light-emitting layer, when the partial exposure using laser irradiation or a photomask described above is adopted as a technique for each light irradiation, the step of the application to the step of the removal described above may be repeatedly performed according to the luminescent color of the corresponding light-emitting element. For example, after the second light-emitting layer 8G illustrated in FIG. 7B is formed, the step of the application to the step of the removal may be performed two more times in a total of three times for forming the first light-emitting layer 8R and the third light-emitting layer 8B.

Here, according to a kind of the light-emitting layer 8 to be formed, a kind of a solution applied in the step of the application is changed, and the photomask M installed above the array substrate 3 is also changed. Specifically, in the step of the first light irradiation, a position of an opening in the photomask M is changed according to a kind of the light-emitting layer 8 such that the light irradiation is performed only on a position overlapping with a position of the light-emitting layer 8 to be formed.

As described above, the light-emitting layer 8 illustrated in FIG. 7C including the first light-emitting layer 8R, the second light-emitting layer 8G, and the third light-emitting layer 8B is formed.

Note that, in the present embodiment, the technique for forming the light-emitting layer 8 partitioned by the edge covers 14 for each light-emitting element has been described. However, when partial exposure using laser irradiation or a photomask is adopted for the light irradiation, light irradiation can be individually performed on a position overlapping with each of the first electrodes 4. Thus, even when the light-emitting layer 8 is not partitioned by the edge covers 14, the light-emitting layer 8 corresponding to each light-emitting element can be formed individually. Therefore, when partial exposure is adopted in the light irradiation, a height of the edge covers 14 may be a height that covers the edge of the first electrode 4.

Note that, in the present embodiment, the method for forming the light-emitting layer 8 in each of the first light-emitting element that emits red light, the second light-emitting element that emits green light, and the third light-emitting element that emits blue light in the step of forming the light-emitting layer described above has been described. However, the step of forming the light-emitting layer described above can be applied to the step of forming the light-emitting layer 8 when a part of the light-emitting element is provided with the light-emitting layer 8 of a kind different from another part of the light-emitting element.

In the present embodiment, the time for performing the first light irradiation on the position corresponding to each of the first light-emitting element 2R, the second light-emitting element 2G, and the third light-emitting element 2B may vary depending on the luminescent color of the light-emitting element. In particular, the irradiation time of the first light irradiation for the position corresponding to the second light-emitting element 2G is preferably shorter than the irradiation time of the first light irradiation for the position corresponding to the first light-emitting element 2R. Furthermore, the irradiation time of the first light irradiation for the position corresponding to the second light-emitting element 2G is preferably longer than the irradiation time of the first light irradiation for the position corresponding to the third light-emitting element 2B.

When the solution 28 is subjected to separately patterning by an ink-jet method in the step of the application, and the light irradiation is performed on the entire coating region, the photomask may be installed above the array substrate 3 and the light irradiation may be started again in the middle of the step of the first light irradiation. In this way, the irradiation time of the first light irradiation can be changed according to the luminescent color of the light-emitting element. When the partial exposure described above is performed, the irradiation time of the first light irradiation may be set different in each partial exposure.

In the step of epitaxially growing the second shell 26 around the quantum dot 20, a growing speed of the second shell 26 is slower as a particle size of the quantum dot 20 increases.

Therefore, as in the configuration described above, a formation condition of each light-emitting layer can be brought closer between the plurality of light-emitting elements by setting different times of the light irradiation according to the luminescent color of the corresponding light-emitting element. Thus, a variation in film thickness of the second shell 26 can be suppressed between the quantum dots 20 having particle sizes different from each other.

Subsequent to the step of forming the light-emitting layer, the second charge transport layer 10 is formed (step S6). The second charge transport layer 10 may be applied and formed in common to all of the subpixels by a spin coat technique or the like.

Finally, the second electrode 12 is formed (step S7). The second electrode 12 may be film-formed in common to all of the subpixels by vapor deposition or the like. As described above, the light-emitting element layer 2 is formed on the array substrate 3, and the light-emitting device 1 illustrated in FIG. 1 is obtained.

In the method for manufacturing the light-emitting device 1 according to the present embodiment, after the quantum dot 20 having the core/shell structure is applied, the second shell 26 epitaxially grows around the first shell 24 of each quantum dot 20. Thus, a film thickness of the shell in each quantum dot 20 can be made thicker than that when the quantum dots 20 having the core/shell structure are simply layered.

For example, in a quantum dot having the core/shell structure, it is conceivable to increase a film thickness of a shell in order to reduce exudation of electrons injected into the core of the quantum dot. However, when quantum dots having a thick film thickness of a shell are layered to form quantum dots, a filling rate of the quantum dots is low with respect to the volume of a light-emitting layer. Thus, it is difficult to achieve sufficient density of the quantum dots in the light-emitting layer, resulting in a decrease in luminous efficiency of a light-emitting element.

In the method for manufacturing the light-emitting device 1 according to the present embodiment, the quantum dot 20 including a thin first shell 24 is applied, and the second shell 26 is then formed on each quantum dot 20. In the light-emitting layer 8 according to the present embodiment, a film thickness of the shell formed around the core 22 can be considered as a total film thickness of the first shell 24 and the second shell 26.

As a result, the density of the quantum dots 20 in the light-emitting layer 8 can be enhanced compared to the case of simply layering the quantum dots provided with the shells having the same film thickness. Thus, while reducing the electron exudation from the quantum dot 20, the density of the quantum dots 20 in the light-emitting layer 8 is improved, thereby resulting in an improvement in luminous efficiency of the light-emitting device 1.

According to NPL 1, the average value of a random close packing ratio in the packing of rigid spheres is approximately 63.66 percent. Accordingly, in the present embodiment, the proportion of the volume of the quantum dot structure 16 in the light-emitting layer 8 is preferably greater than or equal to 63.7 percent. With the above configuration, the density of the quantum dots 20 in the light-emitting layer 8 can be enhanced compared to the case of randomly layering quantum dots each provided with a shell whose film thickness is equal to the total film thickness of the first shell 24 and second shell 26.

In the present embodiment, an average film thickness of the first shell 24 from the outer surface of the core 22 is less than a minimum film thickness of the second shell 26. Thus, the quantum dots 20 can be more densely layered before the step of the first light irradiation, and the second shell 26 having a relatively thick film thickness can be formed in the subsequent step of the first light irradiation.

Therefore, in the step of the first light irradiation, the first shell 24 and the second shell 26 having a film thickness that can sufficiently reduce the electron exudation from the core 22 can be formed, derived from the electron wave function, while the quantum dots 20 are densely layered. Thus, according to this configuration, the density of the quantum dots 20 in the quantum dot structures 16 can be increased while sufficiently ensuring a film thickness of the first shell 24 and the second shell 26.

In the present embodiment, the edge covers 14 and the first charge transport layer 6 are formed after the formation of the first electrode 4 including the oxide semiconductor film 4A, and then the light-emitting layer 8 is formed. Thus, in the step of forming the light-emitting layer 8, heat from the oxide semiconductor film 4A propagates through the first electrode 4, the edge covers 14, and the first charge transport layer 6. Therefore, it is preferable that the first electrode 4, the edge covers 14, and the first charge transport layer 6 contain a material having heat resistance with respect to heating in the step of the first light irradiation described above.

Note that, as long as propagation of heat from the oxide semiconductor film 4A to the array substrate 3 can be prevented, it is not necessary for the array substrate 3 to have high heat resistance. The array substrate 3 may be, for example, a glass substrate containing alkali glass or the like. Further, the array substrate 3 may be an organic substrate containing an organic material such as polyimide. Furthermore, the array substrate 3 may contain a flexible material such as PET, and may achieve a flexible light-emitting device 1.

For example, when the light-emitting element layer 2 forms a bottom-emitting type light-emitting element and the first electrode 4 is an anode electrode, ITO is commonly used for the first electrode 4. ITO is preferable because ITO absorbs ultraviolet light and, furthermore, has a higher transmittance to visible light. Furthermore, in order to suppress an increase in specific resistance due to heating in the above-mentioned heating steps, the first electrode 4 preferably includes a material having high heat resistance such as a composite material of FTO and ITO. When the first charge transport layer 6 is a hole transport layer, it is preferable to contain an inorganic material having higher heat resistance than an organic material, such as NiO, MgNiO, Cr₂O₃, Cu₂O, or LiNbO₃.

In order to achieve a shape having a certain level of height and inclination, an organic material is generally used for the edge cover 14. In the present embodiment, from the perspective of reducing damage caused by heating in the above-mentioned heating steps, the edge cover 14 preferably contains an organic material having a high glass-transition temperature, such as polyimide.

The second charge transport layer 10 and the second electrode 12 are formed after the light-emitting layer 8 is formed. Accordingly, a material not having heat resistance against the heating in the step of the first light irradiation described above can be employed for the material of the second charge transport layer 10 and the second electrode 12. For example, the second charge transport layer 10 may contain a material used for a conventionally known electron transport layer, and the second electrode 12 may contain a material used for a conventionally known cathode electrode.

### Second Embodiment

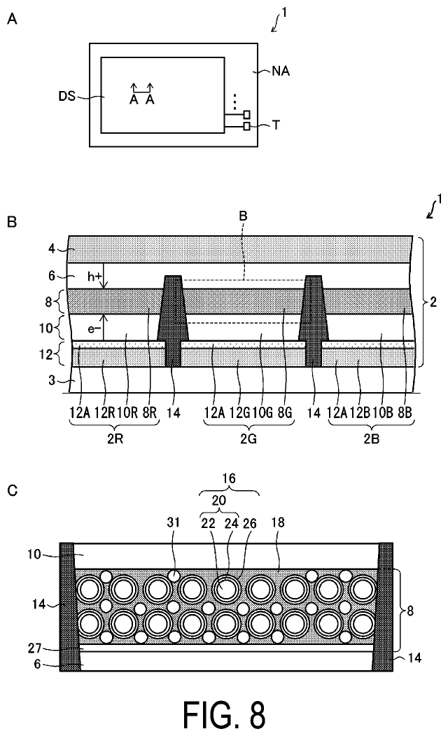

FIG. 8A is a schematic top view of a light-emitting device 1 according to the present embodiment. FIG. 8B is a cross-sectional view taken along a line A-A in FIG. 8A. FIG. 8C is an enlarged cross-sectional view of a region B in FIG. 8B.

The light-emitting device 1 according to the present embodiment may have the same configuration as that of the light-emitting device 1 according to the previous embodiment except that the layering order of each of the layers in a light-emitting element layer 2 is reversed. In other words, the light-emitting element layer 2 according to the present embodiment includes a second charge transport layer 10, a light-emitting layer 8, a first charge transport layer 6, and a first electrode 4, which are sequentially layered from the lower layer on a second electrode 12.

In comparison with the light-emitting element 1 according to the previous embodiment, each of the second electrode 12 and the second charge transport layer 10 is separated by edge covers 14. In particular, in the present embodiment, the second electrode 12 is, by the edge covers 14, separated into a second electrode 12R for a first light-emitting element 2R, a second electrode 12G for a second light-emitting element 2G, and a second electrode 12B for a third light-emitting element 2B. Further, the second charge transport layer 10 is, by the edge covers 14, separated into a second charge transport layer 10R for the first light-emitting element 2R, a second charge transport layer 10G for the second light-emitting element 2G, and a second charge transport layer 10B for the third light-emitting element 2B.

In comparison with the light-emitting element 1 according to the previous embodiment, the first charge transport layer 6 and the first electrode 4 are not separated by the edge covers 14, and are each formed in a shared manner.

In the present embodiment, the first electrode 4 may be a transparent electrode and the second electrode 12 may be a reflective electrode. Therefore, light from the light-emitting layer 8 passes through the first charge transport layer 6 and the first electrode 4, and is emitted from a light-emitting face DS to the outside of the light-emitting device 1. Due to this, the light-emitting device 1 is configured as a top-emitting type light-emitting device. Because of this, in the present embodiment, an array substrate 3 need not necessarily be a transparent substrate.

In the present embodiment, instead of the first electrode 4, the second electrode 12 includes an oxide semiconductor film 12A on a surface. Here, in order to make the second electrode 12 as a reflective electrode, the second electrode 12 may include a metal thin film closer to the array substrate 3 side than the oxide semiconductor film 12A. In the present embodiment, the second electrode 12 corresponds to a first electrode, and the second charge transport layer 10 corresponds to a first charge transport layer. Therefore, an inorganic film 27 formed by epitaxially growing an inorganic precursor 30 is formed at an interface between the present embodiment light-emitting layer 8 and the second charge transport layer 10 (first charge transport layer), i.e., a surface of the second charge transport layer 10.

The light-emitting device 1 according to the present embodiment can be manufactured by performing each of the steps illustrated in FIG. 2 in the order of step S1, step S7, step S3, step S6, step S5, step S4, and step S2 in a similar manner to that of the previous embodiment. Here, in step S7, by forming a metal thin film, and then forming the oxide semiconductor film 12A on the metal thin film, the second electrode 12 having a layered structure of the metal thin film and the oxide semiconductor film 12A may be formed.

Thus, in the present embodiment, the light-emitting layer 8 is formed after the formation of the array substrate 3, the second electrode 12, the edge covers 14, and the second charge transport layer 10. Therefore, it is preferable that the second electrode 12, the edge covers 14, and the second charge transport layer 10 contain a material having heat resistance with respect to heating in the above-mentioned heating step.

For example, when the light-emitting element layer 2 forms a top-emitting type light-emitting element and the second electrode 12 is a cathode electrode, the second electrode 12 preferably contains, as the metal thin film, a metal material with a high melting point from the perspective of enhancing heat resistance with respect to heating in the heating step described above. For example, it is preferable for the second electrode 12 to contain a metal such as Al or Ag, or an intermetallic compound such as AgMg. When the second charge transport layer 10 is an electron transport layer, it is preferable to contain an inorganic material having higher heat resistance than an organic material, such as MgO. The materials described above are also materials used as a cathode electrode material and an electron transport layer material in general.

The first charge transport layer 6 and the first electrode 4 are formed after the light-emitting layer 8 is formed. Accordingly, a material not having heat resistance against the heating in the above-mentioned heating step can be employed for the material of the first charge transport layer 6 and the first electrode 4. For example, the first charge transport layer 6 may contain a material used for a conventionally known hole transport layer, and the first electrode 4 may contain a transparent conductive material used for a conventionally known anode electrode, such as ITO.

The light-emitting device 1 according to the present embodiment has a low level of necessity to change the materials of each layer in the light-emitting element layer 2 in comparison with the light-emitting device 1 according to the previous embodiment. Accordingly, the light-emitting device 1 according to the present embodiment can improve the degree of freedom in material selection in comparison with the light-emitting device 1 according to the previous embodiment.

In the present embodiment, the second electrode 12 is a reflective electrode. According to the configuration, in each light irradiation described above, not only light directly emitted to the quantum dots 20, but also light that has reached the second electrode 12 once and is reflected by the second electrode 12 can be effectively used as light in each light irradiation. Thus, the step of the light irradiation in the present embodiment can reduce intensity of the light irradiation required to irradiate the oxide semiconductor film 4A with sufficient light compared to the step of the light irradiation in the previous embodiment.

In the present embodiment, a top-emitting type light-emitting device 1 is manufactured by reversing the forming order of the light-emitting element layer 2 in the previous embodiment. However, no such limitation is intended, and in the present embodiment, the light-emitting element layer 2 may be formed in the same formation order as that in the previous embodiment to manufacture the top-emitting type light-emitting device 1. In this case, the first electrode 4 is formed as a reflective electrode in which the metal thin film and the oxide semiconductor film 4A are layered, and the second electrode 12 is formed as a transparent electrode, and thus the top-emitting type light-emitting device 1 can be manufactured.

### Third Embodiment

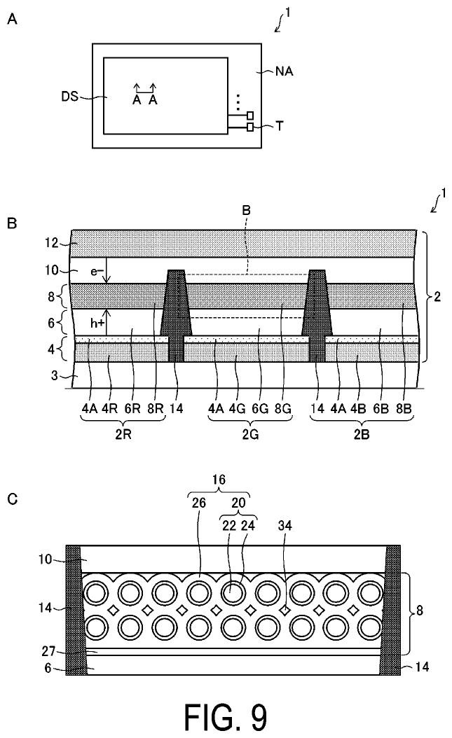

FIG. 9A is a schematic top view of a light-emitting device 1 according to the present embodiment. FIG. 9B is a cross-sectional view taken along a line A-A in FIG. 9A. FIG. 9C is an enlarged cross-sectional view of a region B in FIG. 9B.

The light-emitting device 1 according to the present embodiment may have the same configuration as that of the light-emitting device 1 of the first embodiment except that a light-emitting layer 8 does not include a ligand 18. As illustrated in FIG. 9C, the light-emitting layer 8 may include a void 34 in a space not filled with a quantum dot structure 16.

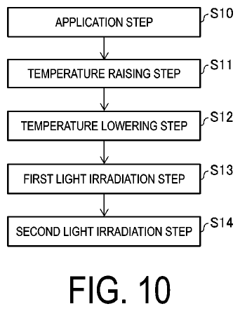

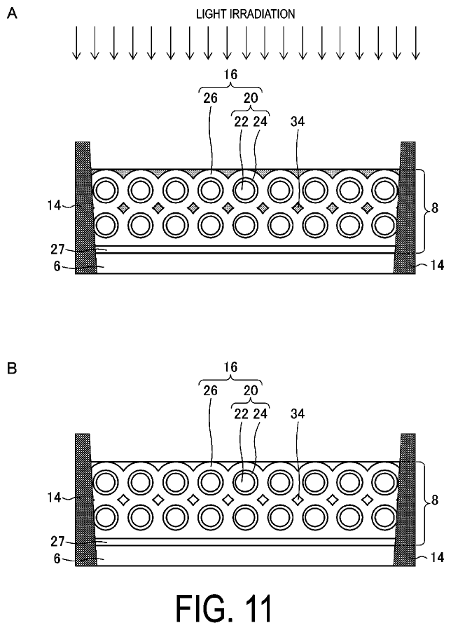

The light-emitting device 1 according to the present embodiment is manufactured by the same method except for step S5, that is, the step of forming the light-emitting layer among the steps illustrated in FIG. 2. The step of forming the light-emitting layer of the light-emitting device 1 according to the present embodiment will be described in more detail with reference to FIGS. 10 to 11B.

FIG. 10 is a flowchart for describing the step of forming the light-emitting layer corresponding to a step of forming a quantum dot layer in the present embodiment. FIGS. 11A and 11B are forming-step cross-sectional views for describing the step of forming the light-emitting layer.

In the step of forming the light-emitting layer according to the present embodiment, the same method as that described in the first embodiment is performed from step S10 to step S13. At the point in time of the completion of step S13, the quantum dot structure 16, the ligand 18, and an inorganic film 27 are formed in an upper layer relative to a first charge transport layer 6, as illustrated in FIG. 11A. Further, in the present embodiment, quantum dots 20 are connected to each other via a second shell 26. The second shell 26 and the inorganic film 27 are connected to each other.

In the present embodiment, subsequent to step S12, a step of second light irradiation is performed in which second light irradiation is additionally performed to heat an oxide semiconductor film 4A in such a manner that the oxide semiconductor film 4A has a temperature equal to or higher than a temperature T4 (step S14). In the second light irradiation, ultraviolet light may be emitted as in the first light irradiation, or light having a great amount of energy per unit time than the light emitted in the first light irradiation may be emitted. The temperature T4 is higher than a reaction temperature T3 of an inorganic precursor 30, and is equivalent to a boiling point of the ligand 18. For example, in the case where the ligand 18 is the aforementioned TOPO, the temperature T4 is 411.2 degrees Celsius.

When the temperature of the ligand 18 reaches the temperature T4 by heating the oxide semiconductor film 4A in the step of the second light irradiation, evaporation of the ligand 18 begins. Thus, in the step of the second light irradiation, the ligand 18 vaporizes, thereby obtaining the light-emitting layer 8 without the ligand 18 as illustrated in FIG. 11B.

In the present embodiment, since at least one set of quantum dots 20 is connected via the second shell 26, an area of the outer surface of the second shell 26 is smaller in the above one set of quantum dots 20 than that in the case of not being connected. That is, in the present embodiment, an area of the outer surface of the quantum dot structure 16 can be reduced compared to the case where the quantum dots are simply layered.

By reducing the area of the outer surface of the quantum dot structure 16, the area of the surface of the second shell 26, through which moisture may infiltrate from the outside, can be reduced. Accordingly, this configuration may reduce damage to the second shell 26 due to the moisture infiltration, and may consequently suppress degradation in a surface protection function of the quantum dot 20 of the second shell 26 due to the damage described above.

When the ligand 18 coordinates on the outer surface of the quantum dot structure 16, the reduction of the area of the outer surface makes it possible to reduce the ligand 18 possible to be damaged by the moisture infiltration. Accordingly, the damage to the second shell 26 due to the loss of the protection function by the ligand 18 for the second shell 26 due to the damage described above can be reduced.

By reducing the area of the outer surface of the quantum dot structure 16, the surface area of the second shell 26 possible to be damaged when the light-emitting device 1 is driven can be reduced. Thus, the above-discussed configuration may reduce damage to the second shell 26 accompanying the drive of the light-emitting device 1, and may consequently reduce the formation of defects in the second shell 26 due to the damage. As a result, by reducing the area of the outer surface of the quantum dot structure 16, the occurrence of a non-emitting process caused by recombination of electrons and holes in the defects is suppressed, and consequently a decrease in luminous efficiency of the light-emitting device 1 is suppressed.

As described above, because of the outer surface of the quantum dot structure 16 being small, the area of the outer surface of the quantum dot structure 16 possible to be damaged can be reduced, and deactivation of the quantum dots 20 due to damage to the quantum dot structure 16 can be reduced.

Note that, in the step of the first light irradiation performed prior to the step of the second light irradiation in the present embodiment, the partial exposure using laser irradiation or a photomask described in the first embodiment may be adopted for the light irradiation. In this case, after the step of the application to the step of the removal are repeatedly performed according to the luminescent color of the corresponding light-emitting element, the second light irradiation described above may be performed on a position overlapping with a position where the solution is applied in the step of the application.

In this way, after the light-emitting layer 8 including the ligand 18 is formed for each luminescent color of the light-emitting element, the ligand 18 in the light-emitting layer 8 can be vaporized at once. Thus, according to the configuration described above, the number of times of performing the second light irradiation can be reduced compared to the case of individually performing the second light irradiation, thereby resulting in a reduction in manufacturing cost.

The light-emitting device 1 according to the present embodiment does not include the ligand 18 in the light-emitting layer 8. Generally, a ligand that coordinates with quantum dots often includes an organic material. Thus, the light-emitting layer 8 according to the present embodiment that does not include the ligand 18 has a low content of an organic material with respect to an inorganic material, and is resistant to deterioration due to moisture permeation or the like. Therefore, the light-emitting device 1 according to the present embodiment can further improve reliability.

Here, from the description of NPL 1 described above, the average value of the proportion of the voids that are not occupied by rigid spheres in the randomly closest packed space of the rigid spheres is approximately 36.34 volume percent. Therefore, for example, a volume ratio of an organic matter to an inorganic matter in the light-emitting layer 8 is preferably equal to or less than 36.3 volume percent. In this case, a proportion of the organic matter in the light-emitting layer 8 can be reduced compared to a case of a light-emitting layer in which conventional quantum dots are randomly closest packed and a void between the quantum dots is filled with an organic ligand. Therefore, with the configuration described above, the reliability of the light-emitting layer 8 can be more efficiently improved.

Note that, in the present specification, expression of “not including a ligand” refers to not substantially including a ligand. For example, the light-emitting layer 8 in the present embodiment may have a residue of impurities or ligands being left to the extent that the reliability of the light-emitting layer 8 is not significantly reduced. Specifically, the light-emitting layer 8 in the present embodiment may have a residue of the impurities or the ligands described above that is approximately 3 volume percent of the entire volume of the light-emitting layer 8.

### Fourth Embodiment

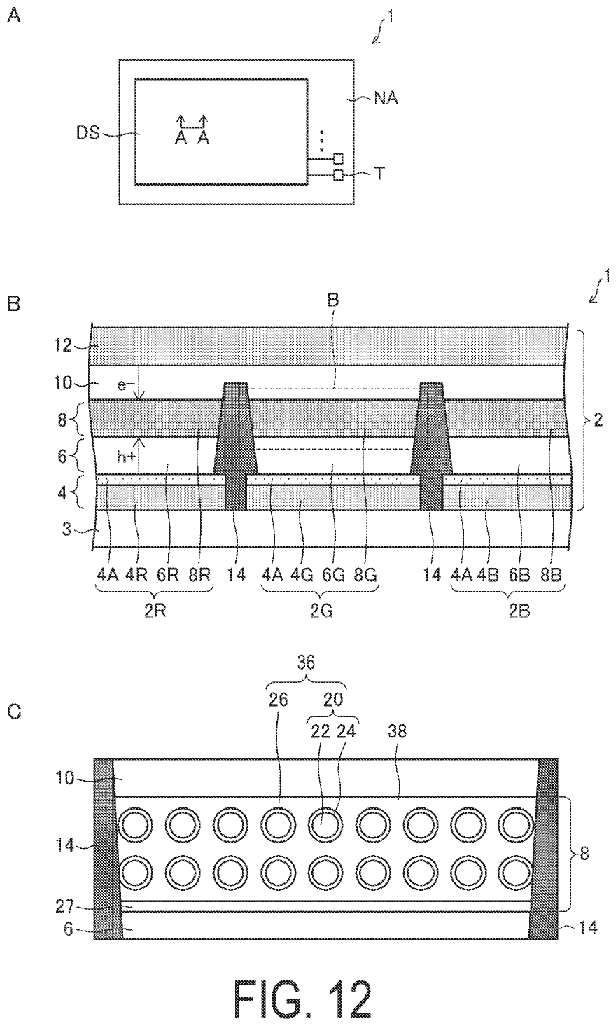

FIG. 12A is a schematic top view of a light-emitting device 1 according to the present embodiment. FIG. 12B is a cross-sectional view taken along a line A-A in FIG. 12A. FIG. 12C is an enlarged cross-sectional view of a region B in FIG. 12B.

The light-emitting device 1 according to the present embodiment may have the same configuration as that of the light-emitting device 1 according to the previous embodiment except that a light-emitting layer 8 includes a quantum dot structure 36 in place of the quantum dot structure 16 and a second charge transport layer 10 is an oxide of a second shell 26. Except for the points described above, the light-emitting device 1 according to the present embodiment may have the same configuration as that of the light-emitting device 1 according to the previous embodiment.

As illustrated in FIG. 12C, the quantum dot structure 36 includes a second shell 38 in addition to a quantum dot 20 and the second shell 26. The second shell 38 is formed of the same material as the second shell 26 and fills at least a part of a void around the second shell 26.

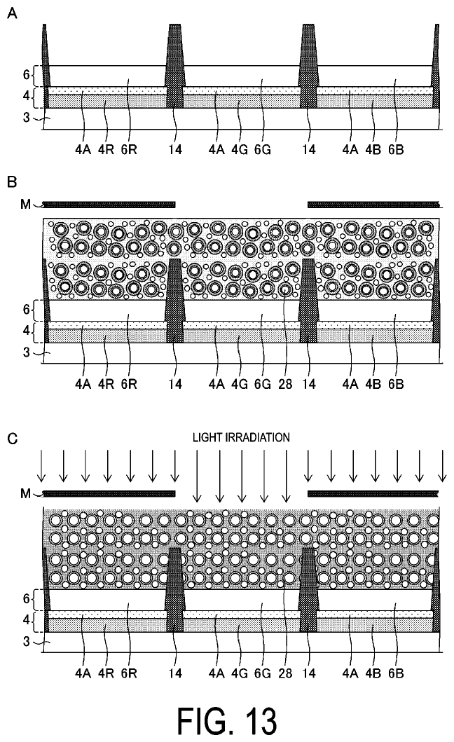

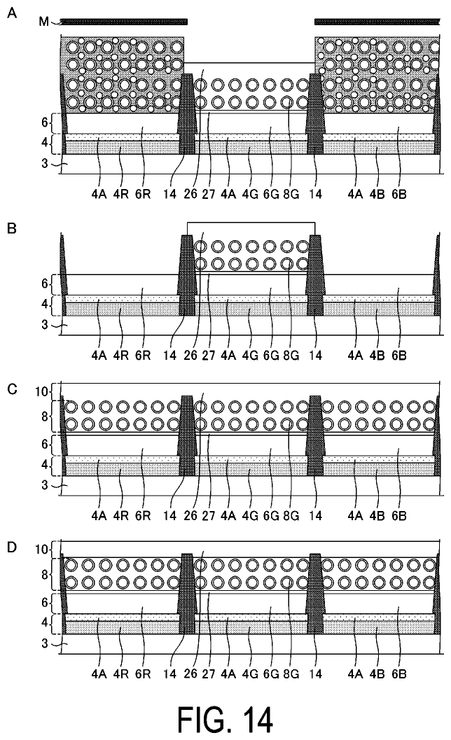

The light-emitting device 1 according to the present embodiment is manufactured by the same method except for step S5 and step S6, that is, the step of forming the light-emitting layer and the step of forming the second charge transport layer among the steps illustrated in FIG. 2. The step of forming the light-emitting layer of the light-emitting device 1 and the step of forming the second charge transport layer thereof according to the present embodiment will be described in more detail with reference to FIGS. 13A to 14D.

FIGS. 13A to 14D are forming-step cross-sectional views for describing the step of forming the light-emitting layer corresponding to a step of forming a quantum dot layer in the present embodiment. Note that FIGS. 13A to 14D illustrate not only a position where a second light-emitting layer 8G is formed, but also illustrate a position where a first light-emitting layer 8R and a third light-emitting layer 8B are formed.

As illustrated in FIG. 13A, a first electrode 4 and a first charge transport layer 6 that are partitioned by edge covers 14 are formed on an array substrate 3 immediately before the step of forming the light-emitting layer is performed. In the present embodiment, a solution 28 is applied to the array substrate 3, similarly to the step of the application described above. Here, in the present embodiment, a proportion of an inorganic precursor 30 in the applied solution 28 is greater than that in the embodiments described above.

Next, a photomask M illustrated in FIG. 13B is installed between the step of the application and the step of the first light irradiation. Also in the present embodiment, when the photomask M is installed above the array substrate 3, an opening is formed such that the opening is formed only in a position overlapping with a first electrode 4G. That is, as illustrated in FIG. 13B, when the photomask M is installed above the array substrate 3, the top of the solution 28 in a position that does not overlap with the first electrode 4G is shielded by the photomask M. Thereafter, the step of the temperature raising and the step of the temperature lowering are performed. Note that the installation of the photomask M may be performed before or after the step of the temperature raising and the step of the temperature lowering, or may be performed between the step of the temperature raising and the step of the temperature lowering.

By performing the step of the first light irradiation after the photomask M is installed, light irradiation is performed only on an oxide semiconductor film 4A in the position overlapping with the first electrode 4G, as illustrated in FIG. 13C. Thus, in the step of the first light irradiation, the quantum dots 20 and the oxide semiconductor film 4A are heated only in the position overlapping with the first electrode 4G. Therefore, as illustrated in FIG. 14A, the second light-emitting layer 8G including the second shell 26 and an inorganic film 27 is formed only in the position overlapping with the first electrode 4G.

Here, also in the step of the first light irradiation in the present embodiment, the second shell 26 is formed from the oxide semiconductor film 4A side. In addition, solution 28 includes a great amount of the inorganic precursor 30. Thus, the formation of the second light-emitting layer 8G progresses while the quantum dots 20 are unevenly distributed on the oxide semiconductor film 4A side in the second shell 26 to be formed. Therefore, as illustrated in FIG. 14A, after the completion of the step of the first light irradiation, an inorganic layer formed of the second shell 26 is formed in the upper layer of the second light-emitting layer 8G.

Note that, in the present embodiment, the step of the second light irradiation described above is also performed in the state illustrated in FIG. 13C. Accordingly, as illustrated in FIG. 14A, the second light-emitting layer 8G that does not include the ligand 18 is formed.

Next, after the photomask M is removed from above the array substrate 3, as illustrated in FIG. 14B, the step of the removal is performed in which the solution 28 is removed from a position overlapping with a position different from the position where the light irradiation is performed. In this way, the step of forming the second light-emitting layer 8G is completed.

The first light-emitting layer 8R and the third light-emitting layer 8B can also be formed by the same method as described above. Here, in the present embodiment, an inorganic layer formed of the second shell 26 is also formed in the upper layer of each of the first light-emitting layer 8R and the third light-emitting layer 8B. Thus, when the step of forming the light-emitting layer 8 is completed, an inorganic layer 10P that is common to the first electrode 4 and formed of the second shell 26 is formed in the upper layer of the light-emitting layer 8.

Note that, in the step of forming the second light-emitting layer 8G, after the completion of the step of the first light irradiation, the step of forming the first light-emitting layer 8R and the third light-emitting layer 8B may be performed without performing the step of the second light irradiation. In this case, a layer of the ligand 18 is formed in the upper layer of the inorganic layer 10P. Next, by performing the second light irradiation described above on a position overlapping with the position where the solution is applied in the step of the application, the ligand 18 can be vaporized together.

In the present embodiment, subsequent to the step of forming the light-emitting layer, oxidation treatment of the second shell 26 is performed from the inorganic layer 10P side. In this way, the second charge transport layer 10 illustrated in FIG. 14D is obtained. Therefore, in the present embodiment, the steps up to step S6 described above can be implemented by the step of forming the charge transport layer in which the oxidation treatment of the inorganic layer 10P is performed.

In the present embodiment, in the step of forming the light-emitting layer, the second shell 26 is formed from the oxide semiconductor film 4A side, and is also formed in the upper layer of the light-emitting layer 8. Thus, the quantum dot structure 36 in which the second shell 38 is formed also in the void 34 in the previous embodiment is obtained.

Thus, the quantum dot structure 36 has a higher proportion of the volume to the entire volume of the light-emitting layer 8 compared to the quantum dot structure 16 in the previous embodiments. That is, the light-emitting layer 8 in the present embodiment has an improvement in filling rate of the shell formed around a core 22 of the quantum dot 20 in the light-emitting layer 8. Therefore, with the configuration described above, the light-emitting device 1 according to the present embodiment can further improve the reliability of the light-emitting layer 8.

Further, in the present embodiment, the second electron transport layer 10 can be obtained by the oxidation treatment of the inorganic layer 10P formed in the upper layer of the light-emitting layer 8. Because of this, an application step to separately apply the material of the second electron transport layer, or the like is not required, which leads to a reduction in tact time and a reduction in manufacturing cost.

In each of the embodiments described above, a case has been described in which the quantum dot layer including the quantum dots 20 is the light-emitting layer 8. However, no such limitation is intended, and the first charge transport layer 6 or the second charge transport layer 10 may be the quantum dot layer including the quantum dots 20, for example. In this manner, in the case where each charge transport layer includes the quantum dots 20, these quantum dots 20 may be provided with a function to transport carriers. In this case, in comparison with a charge transport layer including conventional quantum dots, the stability of the quantum dots 20 in each charge transport layer is improved, so that the efficiency of carrier transport in each of the charge transport layers is improved, leading to an improvement in the luminous efficiency of the light-emitting device 1. Each of the charge transport layers including the quantum dots 20 described above may also be formed by the same technique as the step of forming the quantum dot layer in each of the embodiments.

In each of the above-described embodiments, a display device including a plurality of light-emitting elements and having a display face DS is exemplified to describe the configuration of the light-emitting device 1. However, no such limitation is intended, and the light-emitting device 1 in each of the embodiments described above may be a light-emitting device including a single light-emitting element.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### REFERENCE SIGNS LIST

1 Light-emitting device
2 Light-emitting element layer
2R First light-emitting element
2G Second light-emitting element
2B Third light-emitting element
4 First electrode
6 First charge transport layer
8 Light-emitting layer (Quantum dot layer)
10 Second charge transport layer
10P Inorganic layer
12 Second electrode
16, 36 Quantum dot structure
18 Ligand
20 Quantum dot
22 Core
24 First shell
26, 38 Second shell
27 Inorganic film
28 Solution
30 Inorganic precursor
31 Second quantum dot
32 Solvent
34 Void
M Photomask

1. A method for manufacturing a light-emitting device including, on a substrate, a light-emitting element including a first electrode, a second electrode, a quantum dot layer between the first electrode and the second electrode, and a first charge transport layer between the first electrode and the quantum dot layer, the method comprising:
performing electorode formation of forming, on the substrate, the first electrode including an oxide semiconductor film on a surface; and
forming the quantum dot layer subsequent to the performing electrode formation,
wherein the forming the quantum dot layer includes
performing application of applying, on a position overlapping with the substrate, a solution including a plurality of quantum dots, a ligand, an inorganic precursor, and a solvent, the plurality of quantum dots each including a core and a first shell coating the core, the ligand coordinating with each of the plurality of quantum dots,
performing temperature raising of raising a temperature until the ligand melts and the solvent vaporizes after the performing application, and
performing first light irradiation after the performing temperature raising, and
in the performing first light irradiation,
the inorganic precursor is epitaxially grown around the first shell to form a second shell coating the first shell, and
an inorganic film in which the inorganic precursor is epitaxially grown at an interface between the quantum dot layer and the first charge transport layer is formed.

2. The method for manufacturing a light-emitting device according to claim 1,
wherein the forming the quantum dot layer further includes performing temperature lowering of lowering a temperature to a melting point of the ligand or lower after the performing temperature raising, and,
the performing first light irradiation is performed after the performing temperature lowering.

3. The method for manufacturing a light-emitting device according to claim 1,
wherein in the performing first light irradiation, the oxide semiconductor film absorbs emitted light and generates heat.

4. The method for manufacturing a light-emitting device according to claim 1,
wherein in the performing electrode formation, a metal thin film is formed closer to the substrate side than the oxide semiconductor film.

5. The method for manufacturing a light-emitting device according to claim 1,
wherein a boiling point of the solvent is equal to or higher than the melting point of the ligand, and
in the performing temperature raising, the solvent vaporizes after the ligand melts.

6. The method for manufacturing a light-emitting device according to claim 1,
wherein in the performing first light irradiation, an inorganic layer formed of the same material as a material of the second shell is formed on a side of the quantum dot layer opposite to the substrate.

7. The method for manufacturing a light-emitting device according to claim 6, further comprising:
subsequent to the forming the quantum dot layer,
performing charge transport layer formation of performing oxidation treatment on the inorganic layer and forming a second charge transport layer on a side of the quantum dot layer opposite to the substrate.

8. The method for manufacturing a light-emitting device according to claim 1,
wherein the light-emitting element includes a plurality of the light-emitting elements, and
in the forming the quantum dot layer, the quantum dot layer is formed for each of the plurality of the light-emitting elements, and in a part of the plurality of the light-emitting elements, a quantum dot layer of a kind different from another part of the plurality of the light-emitting elements is formed.

9. The method for manufacturing a light-emitting device according to claim 8,
wherein the plurality of the light-emitting elements include a first light-emitting element configured to emit red light, a second light-emitting element configured to emit green light, and a third light-emitting element configured to emit blue light.

10. The method for manufacturing a light-emitting device according to claim 9,
wherein a concentration of the inorganic precursor in the solution applied on a position corresponding to each of the first light-emitting element, the second light-emitting element, and the third light-emitting element varies depending on a luminescent color of the corresponding light-emitting element.

11. The method for manufacturing a light-emitting device according to claim 10,
wherein, in the performing application, a concentration of the inorganic precursor in the solution applied on the position corresponding to the second light-emitting element is lower than a concentration of the inorganic precursor in the solution applied on the position corresponding to the first light-emitting element and is greater than a concentration of the inorganic precursor in the solution applied on the position corresponding to the third light-emitting element.

12. The method for manufacturing a light-emitting device according to claim 9,
wherein an irradiation time of the light irradiation for the position corresponding to each of the first light-emitting element, the second light-emitting element, and the third light-emitting element varies depending on a luminescent color of the corresponding light-emitting element.

13. The method for manufacturing a light-emitting device according to claim 12,
wherein an irradiation time of the light irradiation for the position corresponding to the second light-emitting element is shorter than an irradiation time of the light irradiation for the position corresponding to the first light-emitting element and is longer than an irradiation time of the light irradiation for the position corresponding to the third light-emitting element.

14. The method for manufacturing a light-emitting device according to claim 8,
wherein each of the plurality of the light-emitting elements individually includes the first electrode, and
in the performing application, the solution is applied on a position overlapping with each of the first electrodes by an ink-jet method.

15. The method for manufacturing a light-emitting device according to claim 1,
wherein partial exposure is performed by laser irradiation in the performing first light irradiation.

16. The method for manufacturing a light-emitting device according to claim 1,
wherein partial exposure is performed using a photomask in the performing first light irradiation.

17. The method for manufacturing a light-emitting device according to claim 15,
wherein a position where light irradiation is performed in the partial exposure is the position overlapping with the first electrode.

18. The method for manufacturing a light-emitting device according to claim 15, further comprising:
subsequent to the performing first light irradiation,
performing removal of removing the solution from a position overlapping with a position different from a position where the light irradiation is performed in the performing first light irradiation.

19. The method for manufacturing a light-emitting device according to claim 18, further comprising:
performing second light irradiation after the performing application, the performing temperature raising, the performing first light irradiation, and the performing removal are repeatedly performed in this order according to a luminescent color of the corresponding light-emitting element to vaporize the ligand.

20. The method for manufacturing a light-emitting device according to claim 19,
wherein light having an amount of energy per unit time greater than an amount of energy per unit time of light emitted in the performing first light irradiation is emitted in the performing second light irradiation to a position overlapping with a position where the solution is applied in the performing application.

21. The method for manufacturing a light-emitting device according to claim 1,
wherein the forming the quantum dot layer further includes performing second light irradiation of additionally performing second light irradiation subsequent to the performing first light irradiation to vaporize the ligand.

22. The method for manufacturing a light-emitting device according to claim 21,
wherein light having an amount of energy per unit time greater than an amount of energy per unit time of light emitted in the first light irradiation is emitted in the second light irradiation.

23. The method for manufacturing a light-emitting device according to claim 21,
wherein in the performing second light irradiation, the oxide semiconductor film absorbs emitted light and generates heat.

24. A light-emitting device including, on a substrate, a light-emitting element including a first electrode, a second electrode, a quantum dot layer between the first electrode and the second electrode, and a first charge transport layer between the first electrode and the quantum dot layer, the light-emitting device comprising:
a plurality of quantum dots each including a core, a first shell coating the core, and a second shell coating the first shell; and
an inorganic film formed at an interface between the quantum dot layer and the first charge transport layer.

25. The light-emitting device according to claim 24,
wherein an average film thickness of the first shell is less than a minimum film thickness of the second shell.

26. The light-emitting device according to claim 24,
wherein the inorganic film and the second shell are separated from each other.
